(19) United States
(12) Patent Application Publication
(10) Pub. No.: US 2009/0101922 A1
(43) Pub. Date: Apr. 23, 2009

(54) LED ARRANGEMENT FOR PRODUCING PURE MONOCHOMATIC LIGHT

(76) Inventor: Chu-Hsien Lin, Hsin-Chu City (TW)

Correspondence Address: WPAT, PC, 7225 BEVERLY ST., ANNANDALE, VA, 22003, US

(21) Appl. No.: 11/876,674

(22) Filed: Oct. 22, 2007

(51) Int. Cl. H01L 33/00

(52) U.S. Cl. 257/89; 257/E33.058

(57) ABSTRACT

In an LED arrangement, two or more LEDs are particularly positioned for the color lights emitted therefrom to be fully mixed to produce a pure monochromatic light. The LEDs may include at least two identical LEDs, and each of the LEDs includes at least two light emitting chips that separately emit a different color light. The LEDs are positioned in a particular manner, so that the light emitting chips located in different LEDs at the same corresponding positions emit different lights. In this manner, the color lights emitted from the LEDs are fully overlapped and mixed to produce a pure monochromatic light having increased illumination intensity and area.

### FIELD OF THE INVENTION

The present invention relates to an LED arrangement, and more particularly to an LED arrangement that enables fully mixture of color lights emitted from at least two LEDs to thereby produce a pure monochromatic light having increased illumination intensity and area.

### BACKGROUND OF THE INVENTION

A light emitting diode (LED) has the advantages of low power consumption, high luminous efficiency, and small in volume. In the early stage, LEDs are usually used as indicator lamps in circuitry, to form an LED array for a large signboard, or in traffic lights at zebra crossings. In recent years, LEDs are also used as a light source for headlights and taillights of some high-class cars.

The LED is internally included one or more light-emitting chips capable of emitting a different color light each. Some of the color lights, such as yellow light, directly emitted from the LED have relatively low stability.

Therefore, yellow light, for example, is usually produced by mixing green light and red light separately emitted from two light emitting chips provided in one LED, so that the yellow light has increased stability for use.

FIG. 1 shows a conventional LED 10 being provided with two light emitting chips 11, 12 that separately emit a different color light. As shown, when viewing in front of the drawing, the chip 11 at the left side in the LED 10 emits a red color light that is biased rightward when being projected forward, and the chip 12 at the right side in the LED 10 emits a green color light that is biased leftward when being projected forward. Moreover, the red light and the green light emitted from the LED 10 are overlapped on a light-projected surface to produce a central yellow light zone 13. Meanwhile, a red light zone 14 and a green light zone 15 are remained at two lateral sides of the central yellow light zone 13. Wherein, the central yellow light zone 13 is an effective area at where the red and the green light are fully mixed. Since a yellow image formed on the light-projected surface by the mixed red and green color lights emitted from the LED 10 still has red and green color lights remained thereat, the light mixture effect of the LED 10 is reduced. For the purpose of producing white light of relatively high brightness from an LED, the semiconductor industrial field has developed an LED 20 provided with light emitting chips 21, 22, and 23 that are capable of emitting red, green, and blue light, respectively. When the red, the green, and the blue chip 21, 22, 23 are arranged in the LED 20 to be equally angularly spaced from one another by 120 degrees, the LED 20 is usually referred to as an RGB (Red, Green, and Blue) LED, as shown in FIG. 2. Please refer to FIG. 3. The red light, the green light, and the blue light emitted from the red, green, and blue light emitting chips 21, 22, 23, respectively, are overlapped on a light-projected surface 24 to produce a central white light zone 25. However, a red light zone 26, a green light zone 27, and a blue light zone 28 still appear on the light-projected surface 24 to locate around the central white light zone 25. As a result, the LED 20 produces only a reduced white light effect.

It is therefore tried by the inventor to develop an LED arrangement that eliminates the color light zones remained around the relatively small central white light zone produced by the conventional RGB LED to enable the production of white light with increased brightness and illumination area. The LED arrangement developed by the inventor may also be applied to other LEDs for mixture of other color lights to produce different pure monochromatic lights.

### SUMMARY OF THE INVENTION

A primary object of the present invention is to provide an LED arrangement, in which LEDs with light mixture function are particularly combined and arranged to thereby produce a monochromatic light with increased illumination intensity and area.

Another object of the present invention is to provide an LED arrangement, which enables different color light zones remained around a central light zone to overlap and mix with one another to thereby produce a monochromatic light the same as that at the central light zone.

To achieve the above and other objects, the LED arrangement according to an embodiment of the present invention includes at least two identical LEDs. Each of the two identical LEDs is provided with at least two light emitting chips that separately emit a different color light. The light emitting chips in each LED are equally angularly spaced. The number of the LEDs to be arranged is equal to that of the light emitting chips in each of the LEDs. In the LED arrangement according to the present invention, the LEDs are located as close as possible to one another, such that light emitted from different LEDs are overlapped on a light-projected surface. The LEDs are so arranged that a following one of the LEDs is rotated by a predetermined rotation angle relative to a preceding one. The rotation angle is equal to an angle at which the light emitting chips in each of the LEDs are angularly spaced. In this manner, the color lights emitted from different LEDs and projected on a surface are mixed to produce a monochromatic light.

In another embodiment of the present invention, the LED arrangement includes at least two LEDs. Each of the LEDs is provided with at least two light emitting chips that separately emit a different color light. The number and the layout of the light emitting chips in all the LEDs are the same, and the light emitting chips located in different LEDs at the same corresponding positions separately emit a different color light, such that lights emitted from the LEDs may be fully mixed with one another to produce a monochromatic light.

In the LED arrangement according to the present invention, the LEDs may be arranged in a straight line or in an endless shape.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 shows how a conventional LED emits lights to form an image;

FIG. 2 shows a conventional LED that emits white light;

FIG. 3 shows how the color lights emitted from three light emitting chips in the white LED of FIG. 2 are overlapped to form an image;

FIG. 4 is a perspective view showing an LED arrangement according to a first embodiment of the present invention;

FIG. 5 is a plan view showing the mounting positions of the LEDs shown in FIG. 4;

FIG. 6 shows the color lights emitted from each of the LEDs shown in FIG. 4 before being overlapped to form an image;

FIG. 7 shows an image formed from the overlapped color lights emitted from each of the LEDs shown in FIG. 4;

FIG. 8 is a perspective view showing an LED arrangement according to a second embodiment of the present invention;

FIG. 9 is a plan view showing the mounting positions of LEDs in an LED arrangement according to a third embodiment of the present invention; and

FIG. 10 is a plan view showing the mounting positions of LEDs in an LED arrangement according to a fourth embodiment of the present invention.

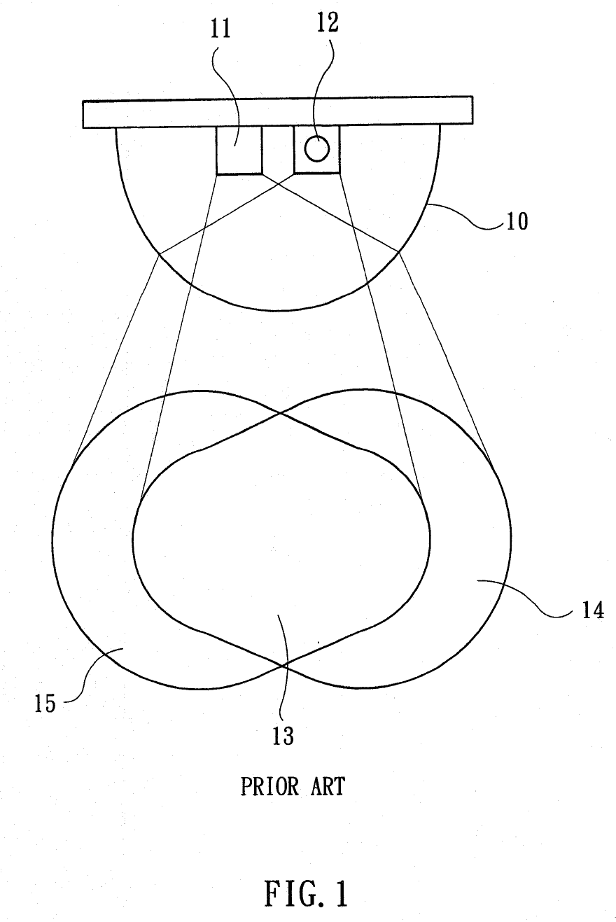

### DETAILED DESCRIPTION OF THE PREFERRED EMBODIMENTS

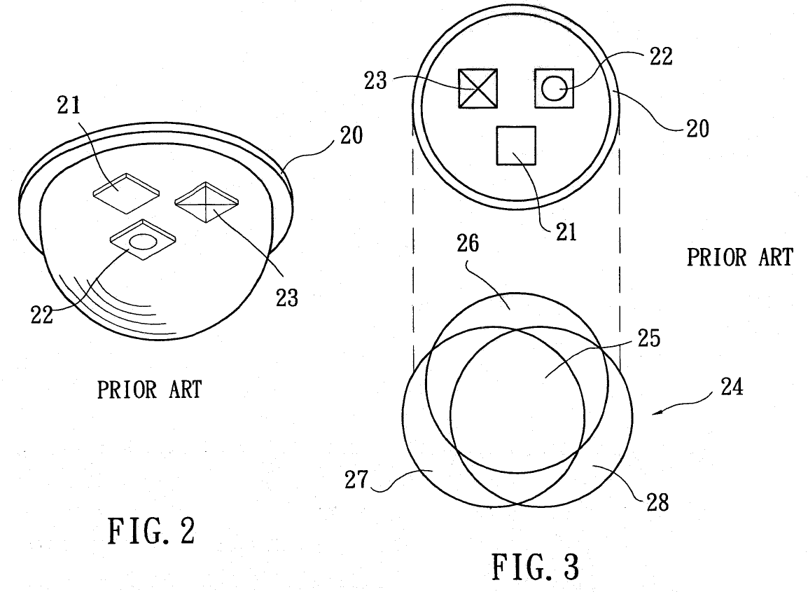

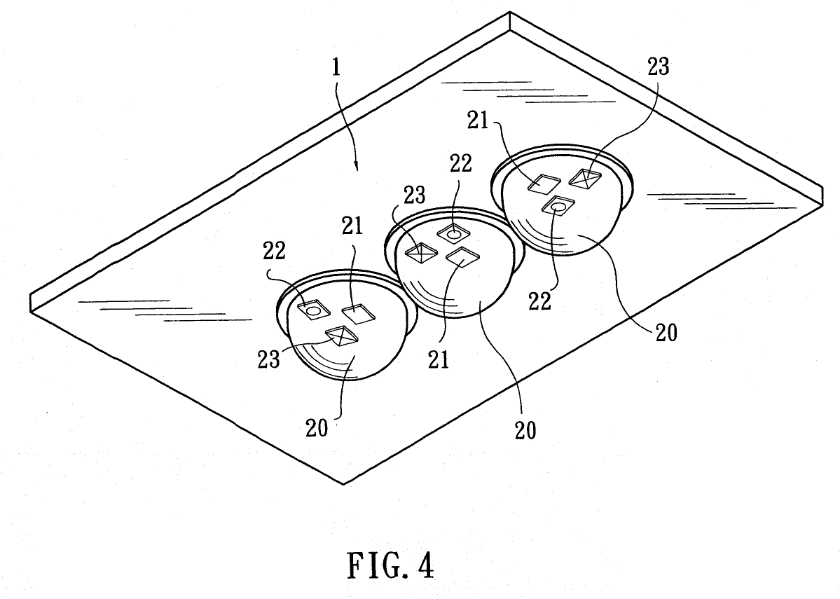

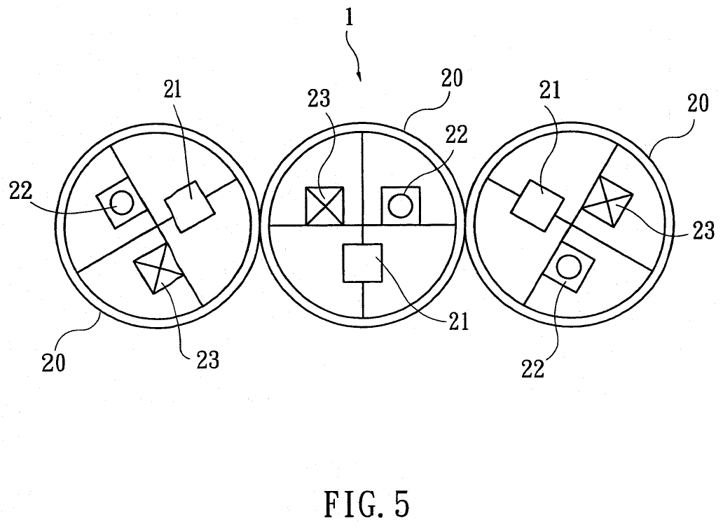

Please refer to FIGS. 4 and 5 that are perspective and plan views, respectively, of an LED arrangement 1 according to a first embodiment of the present invention, in which three identical LEDs 20 as shown in FIG. 2 are positioned in a particular way for producing pure white light. The three LEDs 20 are arranged in a straight line and are separately referred to as middle, right, and left LED 20. Each of the LEDs 20 has three light emitting chips, namely, an R chip 21 capable of emitting red light, a G chip 22 capable of emitting green light, and a B chip 23 capable of emitting blue light. The three light emitting chips 21, 22, 23 in the same one LED 20 are angularly spaced from one another at 120 degrees.

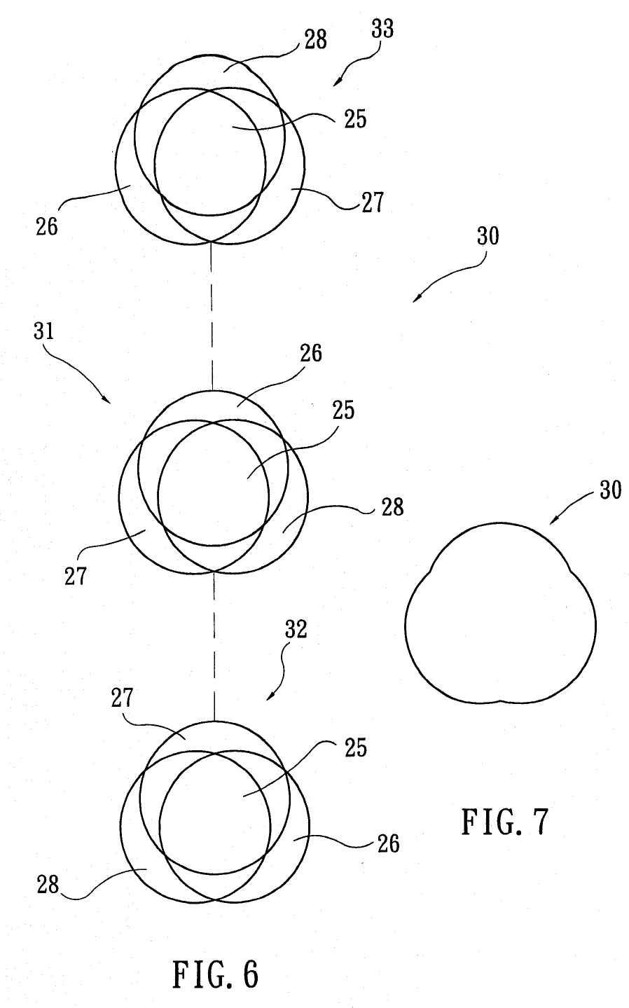

Please also refer to FIG. 6. The three LEDs 20 are so mounted that the right LED 20 is rotated clockwise by 120 degrees relative to the middle LED 20, and the left LED 20 is rotated clockwise by 240 degrees relative to the middle LED 20. Red, green, and blue lights emitted from the same one LED 20 are overlapped on a light-projected surface 30 to produce a central white light zone 25. Meanwhile, there are a red light zone 26, a green light zone 27, and a blue light zone 28 appeared around the central white light zone 25.

The three LEDs 20 arranged in a straight line are positioned as close as possible, so that lights emitted from the three LEDs 20 are overlapped on the light-projected surface 30, which is located away from the LEDs 20 by a certain distance, to increase the intensity of the central white light zone 25.

Taking the LED arrangement 1 shown in FIG. 5 as an example, in the middle LED 20, as viewed in front of the drawing, the R chip 21 is located directly below a center of the middle LED 20, the G chip 22 is located to the right side of and angularly spaced from the R chip 21 at 120 degrees, and the B chip 23 is located to the left side of and angularly spaced from the R chip 21 at 120 degrees. An image 31 formed on the light-projected surface 30 by the color lights emitted from the middle LED 20 has a central white light zone 25, at where the red light, the green light, and the blue light emitted from the middle LED 20 are overlapped. A red light zone 26, a green light zone 27, and a blue light zone 28 are located above, to the left, and to the right of the central white light zone 25, respectively.

Similarly, in the right LED 20, which is clockwise rotated by 120 degrees relative to the middle LED 20 as viewed in front of the drawing, the G chip 22 is located directly below a center of the right LED 20, the B chip 23 is located to the right side of and angularly spaced from the G chip 22 at 120 degrees, and the R chip 21 is located to the left side of and angularly spaced from the G chip 22 by 120 degrees. An image 32 formed on the light-projected surface 30 by the color lights emitted from the right LED 20 has a central white light zone 25, at where the red light, the green light, and the blue light emitted from the right LED 20 are overlapped. A green light zone 27, a blue light zone 28, and a red light zone 26 are located above, to the left, and to the right of the central white light zone 25, respectively.

Similarly, in the left LED 20, which is clockwise rotated by 240 degrees relative to the middle LED 20 as viewed in front of the drawing, the B chip 23 is located directly below a center of the left LED 20, the R chip 21 is located to the right side of and angularly spaced from the B chip 23 at 120 degrees, and the G chip 22 is located to the left side of and angularly spaced from the B chip 23 at 120 degrees. An image 33 formed on the light-projected surface 30 by the color lights emitted from the left LED 20 has a central white light zone 25, at where the red light, the green light, and the blue light emitted from the right LED 20 are overlapped. A blue light zone 28, a red light zone 26, and a green light zone 27 are located above, to the left, and to the right of the central white light zone 25, respectively.

The color lights emitted from the above-mentioned three LEDs 20 closely arranged in a straight line are overlapped on the light-projected surface 30, that is, the three images 31, 32, 33 are overlapped on the light-projected surface 30, so that the central white light zones 25 of the three images 31, 32, 33 are overlapped to produce white light with an increased intensity. Meanwhile, the red light zone 26, the green light zone 27, and the blue light zone 28 produced by the middle, the right, and the left LED 20, respectively, and located above the central white light zones 25 are overlapped on the light-projected surface 30 to produce white light; the green light zone 27, the blue light zone 28, and the red light zone 26 produced by the middle, the right, and the left LED 20, respectively, and located to the left of the central white light zones 25 are also overlapped on the light-projected surface 30 to produce white light; and the blue light zone 28, the red light zone 26, and the green light zone 27 produced by the middle, the right, and the left LED 20, respectively, and located to the right of the central white light zones 25 are also overlapped on the light-projected surface 30 to produce white light. Therefore, lights emitted from the three LEDs 20 arranged as shown in FIGS. 4 and 5 are projected to and overlapped on the light-projected surface 30 to form a pure white light zone, as shown in FIG. 7, of which the white light has an intensity three time as strong as that of the white light from one single LED 20 to therefore meet the light intensity as required by general lighting fixture.

The LED arrangement 1 of the present invention may include more than three LEDs 20, so that the white light produced by the LED arrangement 1 has even higher illumination intensity more suitable for used as a light source of general lighting fixture.

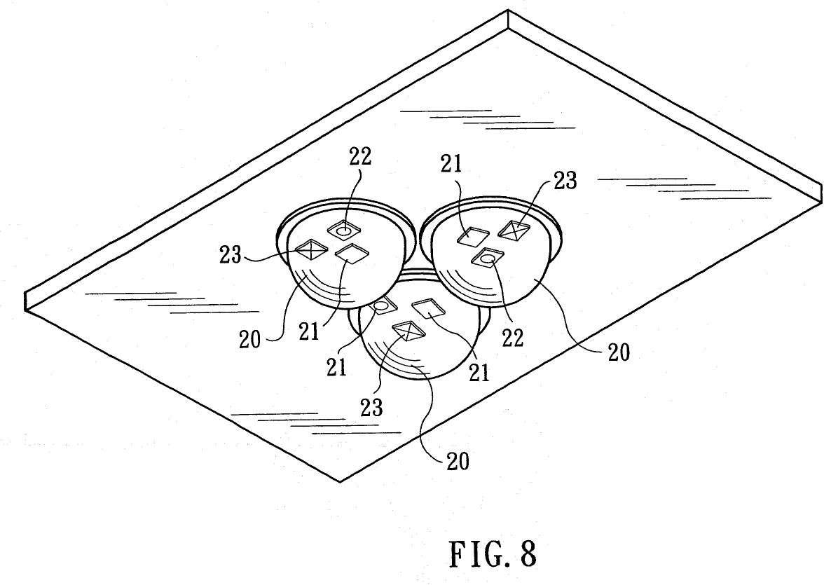

In the LED arrangement 1 according to the first embodiment of the present invention shown in FIGS. 4 and 5, the three LEDs 20 are arranged in a straight line. FIG. 8 shows an LED arrangement according to a second embodiment of the present invention, which is a variant of the LED arrangement 1. In the second embodiment, there are included three LEDs 20 arranged in an equiangular triangle to produce pure white light on a light-projected surface, too.

It is noted the R, G, B light emitting chips 21, 22, 23 of each of the three LEDs 20 in the LED arrangement 1 are equally angularly spaced from each other. And, the number of the LEDs 20 in the LED arrangement 1 is three, which is equal to the number of the light emitting chips 21, 22, 23 in each of the LEDs 20. Moreover, the three LEDs 20 in the LED arrangement 1 are sequentially rotated relative to a preceding one by a fixed rotation angle, and the rotation angle for each of the three LEDs 20 corresponds to the angle at which the R, G, and B chips 21 thereof are spaced from one another, such that the R chip 21, the G chip 22, and the B chip 23 separately provided in the three LEDs 20 are located at the same corresponding angular positions. In this manner, the color lights emitted from the three LEDs 20 in the LED arrangement 1 could be completely and effectively mixed to obtain a monochromatic light across a relatively large area and having a relatively high intensity.

In the case the LED arrangement 1 according to the first embodiment includes more than three LEDs 20, these LEDs 20 may be sequentially arranged in an endless shape, such as a square formed from four LEDs 20, and a regular pentagonal ring shape formed from five LEDs 20.

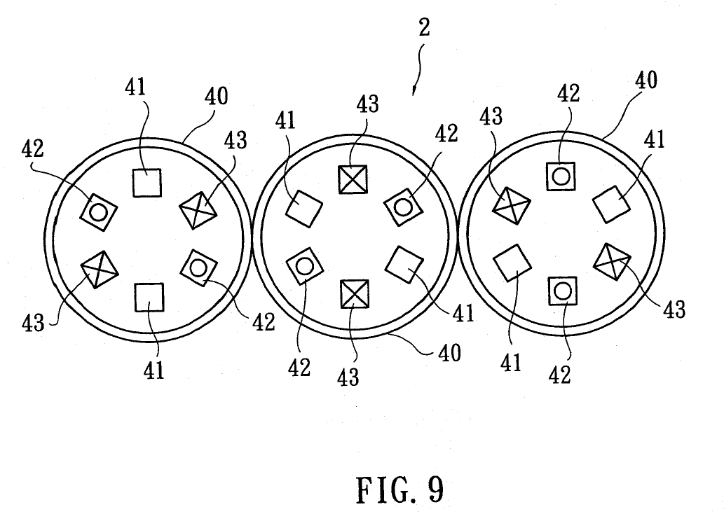

FIG. 9 shows an LED arrangement 2 according to a third embodiment of the present invention. The LED arrangement 2 includes three linearly arranged LEDs 40, namely, a middle, a right, and a left LED 40. Each of the three LEDs 40 is internally provided with two sets of three sequentially arranged light emitting chips 41, 42, 43. The six light emitting chips are equally angularly spaced at an angle of 60°. Wherein, the two chips 41 emit red light and are briefly referred to as R chips 41 herein, the two chips 42 emit green light and are briefly referred to as G chips 42 herein, and the two chips 43 emit blue light and are briefly referred to as B chips 43 herein. The left LED 40 is rotated clockwise by 60 degrees relative to the middle LED 40, and the right LED 40 is rotated clockwise by 120 degrees relative to the middle LED 40, such that each group of three light emitting chips separately located in the three LEDs 40 at the same corresponding positions always includes an R chip 41, a G chip 42, and a B chip 43. Therefore, color lights emitted from the three LEDs 40 are complementary and mixed to produce white light on a light-projected surface.

According to the third embodiment of the present invention illustrated in FIG. 9, when at least two sets of three chips 41, 42, 43 respectively emitting a different color light are cyclically provided in each of the LEDs 40 in the LED arrangement 2, the number of the LEDs 40 in the LED arrangement 2 is equal to the number of color lights emitted from the chips 41, 42, 43. Moreover, the rotation angle for the LEDs 40 is a multiple of 60°, at which the light emitting chips 41, 42, 43 are angularly spaced in each of the LEDs 40. With these arrangements, the light emitting chips separately located in different LEDs 40 at the same corresponding positions always includes chips that separately emit a different color light.

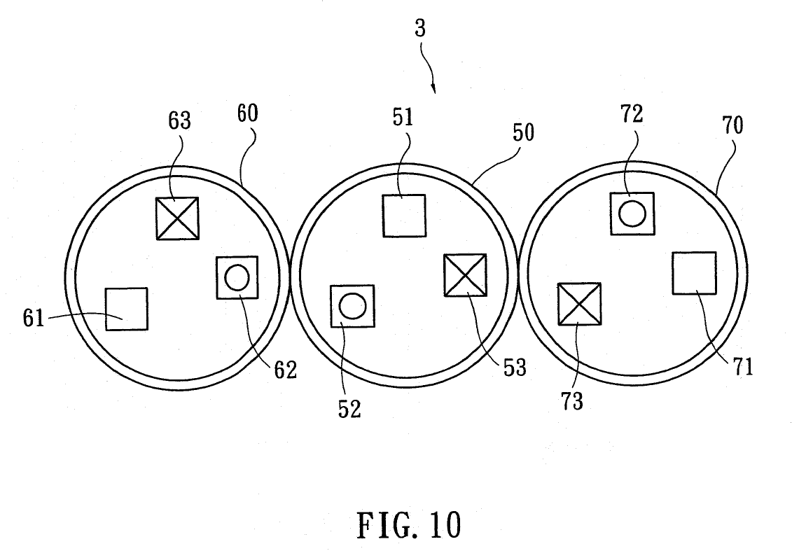

FIG. 10 is a plan view showing an LED arrangement 3 according to a fourth embodiment of the present invention. In the illustrated LED arrangement 3, there are included three LEDs 50, 60, 70. The LEDs 50, 60, 70 are respectively provided with an R chip 51, 61, 71 capable of emitting red light, a G chip 52, 62, 72 capable of emitting green light, and a B chip 53, 63, 73 capable of emitting blue light. The R chip 51, the B chip 63, and the G chip 72 are located in the LEDs 50, 60, 70, respectively, at the same corresponding positions; the G chip 52, the R chip 61, and the B chip 73 are located in the LEDs 50, 60, 70, respectively, at the same corresponding positions; and the B chip 53, the G chip 62, and the R chip 71 are located in the LEDs 50, 60, 70, respectively, at the same corresponding positions.

With these arrangements, the red, green, and blue lights emitted from each of the three LEDs 50, 60, 70 are mixed to produce pure white light.

It is noted that, in the LED arrangement 3, even if the light emitting chips in each of the LEDs 50, 60, 70 are not equally angularly spaced, the color lights emitted from the chips may still be completely mixed to produce a monochromatic light.

In brief, the present invention provides different LED arrangements, in each of which a plurality of LEDs are particularly arranged to enable mixture of color lights emitted from the light emitting chips in the LEDs to produce a pure monochromatic light. With the present invention, the conventional RGB LEDs for emitting white light may be positioned in special manners to produce white light with increased illumination intensity and area, so that LEDs may have expanded applications and be used as a light source for general lighting fixture.

What is claimed is:

1. An LED arrangement, comprising at least two identical LEDs;
each of the at least two identical LEDs including a plurality of light emitting chips in a number the same as that of the LEDs; and the at least two LEDs being positioned as close as possible to one another, so that lights emitted from the at least two LEDs are overlapped on a light-projected surface;
the plurality of light emitting chips in each of the at least two LEDs respectively emitting a different color light, and being equally angularly spaced from one another; and
the at least two LEDs being so positioned that a following one of the LEDs is rotated by a predetermined rotation angle relative to a preceding one; the rotation angle being equal to an angle at which the plurality of light emitting chips in each of the LEDs are angularly spaced, such that the light emitting chips located in different LEDs at the same corresponding positions are chips that emit different color lights.

2. The LED arrangement as claimed in claim 1, wherein the at least two LEDs are arranged in a straight line.

3. The LED arrangement as claimed in claim 1, wherein the at least two LEDs are arranged in an endless shape.

4. An LED arrangement, comprising at least two identical LEDs;
each of the at least two identical LEDs including a plurality of light emitting chips in a number twice as much as that of the LEDs; and the at least two LEDs being positioned as close as possible to one another, so that lights emitted from the at least two LEDs are overlapped on a light-projected surface;
the plurality of light emitting chips in each of the at least two LEDs being equally angularly spaced from one another and divided into two identical sets; and the light emitting chips in each of the two sets respectively emitting a different color light;
the light emitting chips in each of the at least two LEDs that emit the same color light being spaced from each other by other chips that emit other different color lights; and the light emitting chips in each of the at least two LEDs that emit different color lights being sequentially arranged while being equally angularly spaced; and
the at least two LEDs being so positioned that a following one of the LEDs is rotated by a predetermined rotation angle relative to a preceding one, such that the light emitting chips located in different LEDs at the same corresponding positions are chips that emit different color lights.

5. The LED arrangement as claimed in claim 4, wherein the at least two LEDs are arranged in a straight line.

6. The LED arrangement as claimed in claim 4, wherein the at least two LEDs are arranged in an endless shape.

7. A LED arrangement, comprising at least two LEDs;
each of the at least two LEDs including a plurality of light emitting chips in a number the same as that of the LEDs; and the at least two LEDs being positioned as close as possible to one another, so that lights emitted from the at least two LEDs are overlapped on a light-projected surface; and
the plurality of light emitting chips in each of the at least two LEDs respectively emitting a different color light, and the light emitting chips located in different LEDs at the same corresponding positions being chips that emit different color lights, such that color lights emitted from the at least two LEDs may be fully mixed to produce a monochromatic light.

8. The LED arrangement as claimed in claim 7, wherein the at least two LEDs are arranged in a straight line.

9. The LED arrangement as claimed in claim 7, wherein the at least two LEDs are arranged in an endless shape.
